(19) United States
(12) Patent Application Publication
(10) Pub. No.: US 2013/0241558 A1
(43) Pub. Date: Sep. 19, 2013

(54) Magnetic Resonance Tomograph with Cooling Device for Gradient Coils

(71) Applicants: Johann Schuster, Oberasbach (DE); Stefan Stocker, Grossenseebach (DE)

(72) Inventors: Johann Schuster, Oberasbach (DE); Stefan Stocker, Grossenseebach (DE)

(21) Appl. No.: 13/802,741

(22) Filed: Mar. 14, 2013

(30) Foreign Application Priority Data
Mar. 14, 2012 (DE) DE 102012203974.0

(51) Int. Cl. G01R 33/34

(52) U.S. Cl. CPC G01R 33/3403
USPC 324/322

(57) ABSTRACT

A magnetic resonance tomography device includes at least three coil layers. The at least three coil layers are each operable to generate a gradient magnetic field in one of three directions. One cooling layer is arranged between a first and a second of the at least three coil layers. Another cooling layer is arranged between the second and a third of the at least three coil layers.

This application claims the benefit of DE 10 2012 203 974.0, filed on Mar. 14, 2012, which is hereby incorporated by reference.

### BACKGROUND

The present embodiments relate to a magnetic resonance tomography device.

Magnetic resonance devices (MRTs) for the examination of objects or patients using magnetic resonance tomography are known, for example, from DE10314215B4.

A magnetic resonance tomography device MRT has, for example, three-axle gradient coils (e.g., GC or Gradient Coil) that are employed to generate magnetic fields in the direction of three Cartesian spatial axes, for example. In order to generate the desired field strengths, currents of several hundred amperes may be used. The gradient coil conductors may be placed layer by layer on cylindrical surfaces. The gradient coil conductors are exposed to high alternating forces (e.g., Lorentz forces) on account of the arrangement in the base field of the MRT magnets. In order to achieve a mechanical fixing of the conductors and a good thermal coupling with the cooling device, the conductors are, for example, embedded in a resin matrix (e.g., epoxy). The high electrical currents generate thermal losses up to 25 kW.

In order to be able to discharge dissipative power as effectively as possible, cooling hoses are embedded in the resin between the individual coil layers (e.g., several hundred meters of cooling hose per coil and several parallel cooling circuits). The thermal losses formed in the coil windings may be discharged to the heat sink (e.g., a cooling medium such as water) with as minimal a thermal resistance as possible. At the same time, electrical insulation may be established between the copper coils and, if necessary, an electrically conductive cooling medium.

Considerable care is therefore taken in terms of optimizing the space requirement for the individual layers. If a large conductor cross-section is selected for the coil conductor in order to generate less thermal losses, this results in an increased radial space requirement for the overall coil. The larger the radius of a coil layer is selected, the more current is expended to generate the desired magnetic field. The current requirement may be somewhat proportional to the fifth power of the radius (I˜R⁵). The radii may be kept as small as possible, and the layer structure may be provided in as compact a manner as possible. The conductor cross-sections are, for example, selected to be as large in order to achieve an operating temperature of approximately 85° C. during nominal output operation.

### SUMMARY AND DESCRIPTION

The present embodiments may obviate one or more of the drawbacks or limitations in the related art. For example, the cooling of gradient coils in a magnetic resonance tomography (MRT) device may be optimized.

Without necessarily changing the thickness of the cooling layers, the flow rate or the cooling medium, embodiments optimize the cooling of the innermost gradient coil layer compared with known conventional structures.

### BRIEF DESCRIPTION OF THE DRAWINGS

FIG. 1 shows a magnetic resonance tomography (MRT) system;

FIG. 2 shows simplified partial coil layers of a gradient system of an MRT;

FIG. 3 shows a systematic partial section through a known gradient coil cooling of three Cartesian coil layers, having an integrated cooling device and a typical temperature curve in a warm state;

FIG. 4 shows one embodiment of a gradient coil cooling as a systematic, simplified partial section; and

FIG. 5 shows one embodiment of a gradient coil cooling as in FIG. 4, as a systematic, simplified partial section extended by a temperature profile.

### DETAILED DESCRIPTION

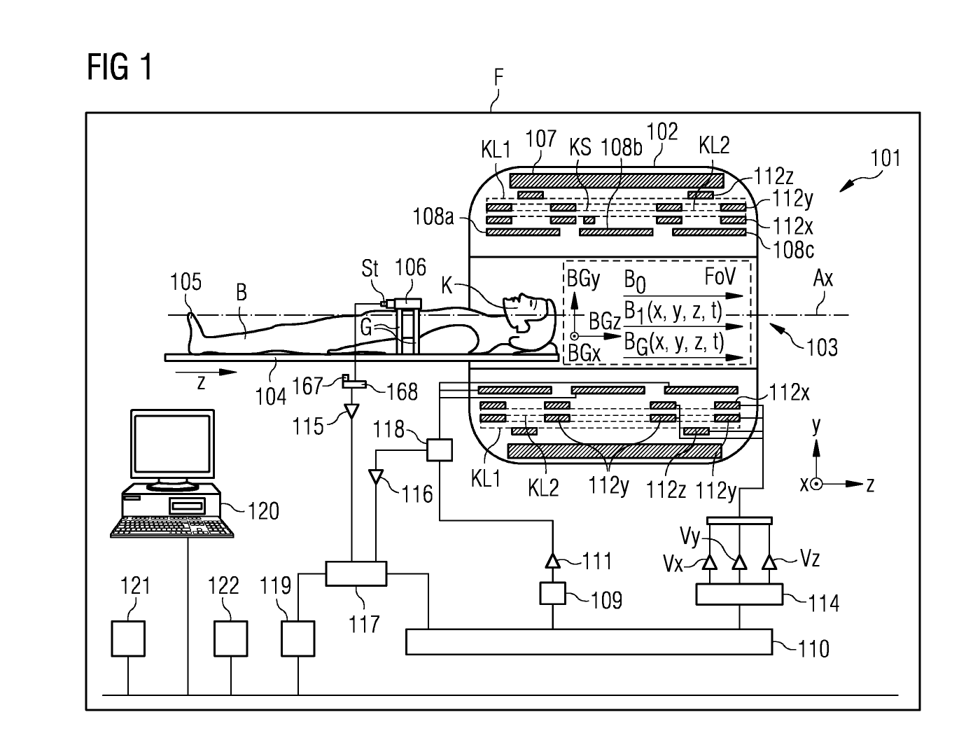

FIG. 1 shows a magnetic resonance imaging device MRT 10 disposed in a shielded room or Faraday cage F. The magnetic resonance imaging device MRT 10 includes a whole body coil 102 with a tubular room 103, for example, into which a patient couch 104 with a body 105 (e.g., of an examination object such as a patient; with or without a local coil arrangement 106) may be moved in the direction of arrow z in order to generate recordings of the patient 105 using an imaging method. The local coil arrangement 106 is arranged on the patient. In a local region (e.g., field of view (FOV)) of the MRT, recordings of a subarea of the body 105 may be generated in the FOV with the local coil arrangement 106. Signals from the local coil arrangement 106 may be evaluated (e.g., converted into images, stored or displayed) by an evaluation device (e.g., including elements 168, 115, 117, 119, 120, 121) of the MRT 101 that may be connected to the local coil arrangement 106 via coaxial cables or radio (e.g., element 167), for example.

In order to examine the body 105 (e.g., an examination object or a patient) using a magnetic resonance device MRT 101 using a magnetic resonance imaging, different magnetic fields attuned as precisely as possible to one another in terms of temporal and spatial characteristics are irradiated onto the body 105. A strong magnet (e.g., a cryomagnet 107) in a measuring cabin with a tunnel-type opening 103 generates a strong static main magnetic field B₀ that amounts, for example, to 0.2 Tesla to 3 or more Tesla. The body 105 to be examined, mounted on a patient couch 104, is moved into an approximately homogenous region of the main magnetic field B0 in the FoV. Excitation of the nuclear spin of atomic nuclei of the body 105 takes place via high frequency magnetic excitation pulses B1(x, y, z, t) that are irradiated via a high frequency antenna (and/or, if necessary, a local coil arrangement) that is shown in FIG. 1 in a very simplified manner as a body coil 108 (e.g. a multipart body coil 108a, 108b, 108c). High frequency excitation pulses are generated, for example, by a pulse generation unit 109 that is controlled by a pulse sequence control unit 110. After amplification by a high frequency amplifier 111, the high frequency excitation pulses are routed to the high frequency antenna 108. The high frequency system shown in FIG. 1 is only indicated schematically. In other embodiments, more than one pulse generation unit 109, more than one high frequency amplifier 111 and a number of high frequency antennas 108, a, b, c are used in a magnetic resonance device 101.

The magnetic resonance device 101 has gradient coils 112x, 112y, 112z, with which magnetic gradient fields B_{G}(x, y, z, t) are irradiated during a measurement for selective slice excitation and local encoding of the measuring signal. The gradient coils 112x, 112y, 112z are controlled by a gradient coil control unit 114 that, similarly to the pulse generation unit 109, is likewise connected to the pulse sequence control unit 110.

Signals emitted by the excited nuclear spin (e.g., the atomic nuclei in the examination object) are received by the body coil 108 and/or at least one local coil arrangement 106, amplified by an associated high frequency preamplifier 116 and further processed and digitalized by a receive unit 117. The recorded measurement data is digitalized and stored as complex numerical values in a k-space matrix. An associated MR image may be reconstructed from the k-space matrix populated with values using a multidimensional Fourier transformation.

For a coil, which may be operated both in transmit and also in receive mode (e.g., the body coil 108 or a local coil 106), the correct signal forwarding is controlled by an upstream transmit/receive switch 118. An image processing unit 119 generates an image from the measurement data. The generated image is shown to a user via a console terminal 120 and/or is stored in a storage unit 121. A central computing unit 122 controls the individual system components.

Images with a high signal/noise ratio (SNR) may be recorded in MR tomography with local coil arrangements (e.g., coils, local coils). The local coil arrangements are antenna systems that are applied in the immediate vicinity on (anterior) and/or below (posterior), on, or in the body 105. With an MR measurement, the excited nuclei induce a voltage into the individual antennas of the local coil. The induced voltage is amplified with a low noise preamplifier (e.g., LNA, preamp) and forwarded to the receive electronics. In order to improve the signal/noise ratio even with highly resolved images, high field systems are used (e.g., 1.5T-12T or more). If more individual antennas may be connected to an MR receive system than there are receivers present, a switching matrix (e.g., RCCS) is integrated between the receive antennas and the receiver. The switching matrix routes the currently active receive channels (e.g., the receive channels that currently lie in the field of view of the magnet) to the existing receiver. More coil elements than there are receivers present may thus be connected, since with a whole body coverage, only the coils that are disposed in the field of view and/or in the homogeneity volume of the magnet are to be read out.

An antenna system may be referred to as a local coil arrangement 106, for example, which may include an antenna element or, as an array coil, a number of antenna elements (e.g., coil elements). These individual antenna elements are embodied, for example, as loop antennas (loops), butterfly, flexible coils or saddle coils. A local coil arrangement includes, for example, coil elements, a pre-amplifier, further electronics (e.g., a balun), a housing, supports and may include a cable with a plug, by which the local coil arrangement is connected to the MRT system. A receiver 168 attached on the system side filters and digitalizes a signal received by a local coil 106 (e.g., by radio) and transfers the data to a digital signal processing device. The digital signal processing device may derive an image or a spectrum from the data obtained by measurement and provides the user with the image and the spectrum for a subsequent diagnosis and/or storage purposes, for example.

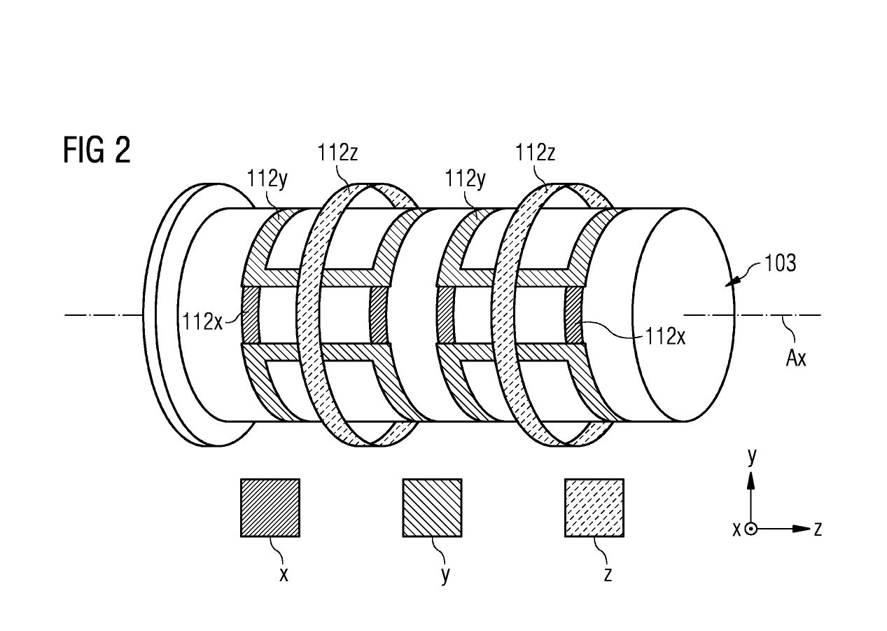

FIG. 2 shows schematic gradient coil layers a, b, c (e.g., a and b for the generation of magnetic fields in the x and y direction) of a gradient system of an MRT 101.

Coils in coil layers a, b, c are embodied by their arrangement for the generation of a gradient magnetic field (BG (x, y, z, t)) in one of three directions x, y, z (e.g., the coil 112z for the generation of a gradient magnetic field in the direction z such that the coil 112z has windings arranged in an approximately circular manner about the axis Ax, z; the coil 112y for the generation of a gradient magnetic field in direction y; and the coil 112x for the generation of a gradient magnetic field in direction x).

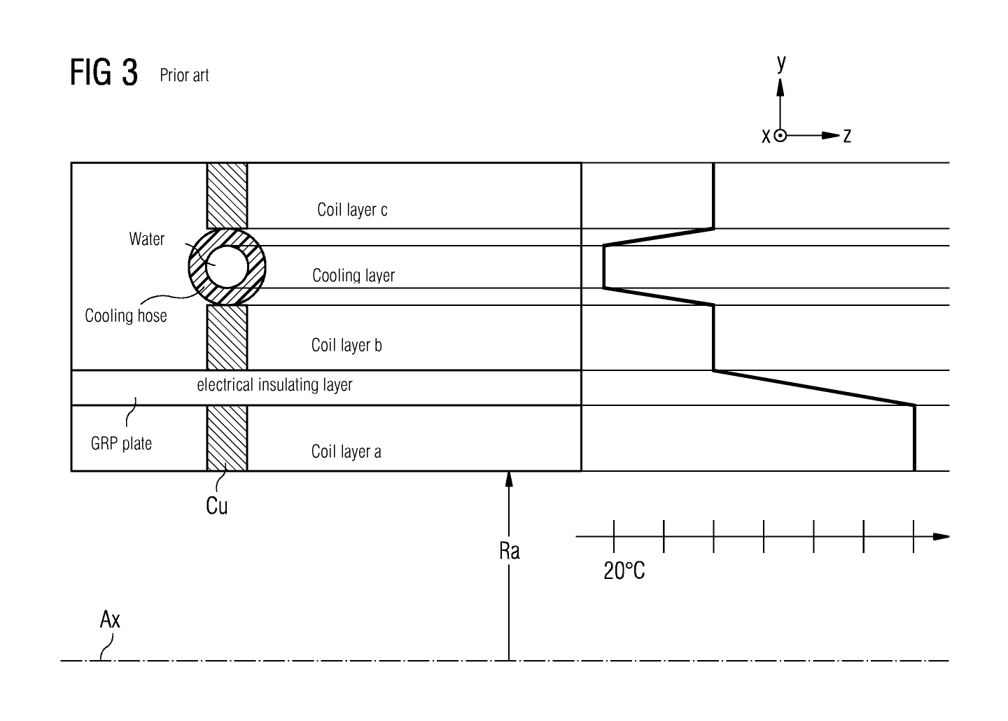

FIG. 3 shows a known gradient coil cooling having transversal coil layers a, b, c for the generation of magnetic fields in x-, y-, and z-directions.

In accordance with the gradient coil cooling shown in FIG. 3, coil layers are arranged far radially inwards in order to retain an efficient structure. A radially outer lying cooling layer discharges heat produced in the coil layers through current into gradient coils. A further coil layer is provided on the cooling layer. The Helmholtz-type wound c-coil, which intrinsically also involves the highest efficiency of the field generation, may be selected. The advantage of the described arrangement may be a high layer efficiency of the two transversal coil layers. The relatively high thermal resistance of the layer remote from the cooling relative to the heat sink is disadvantageous with respect to a possible nominal current load.

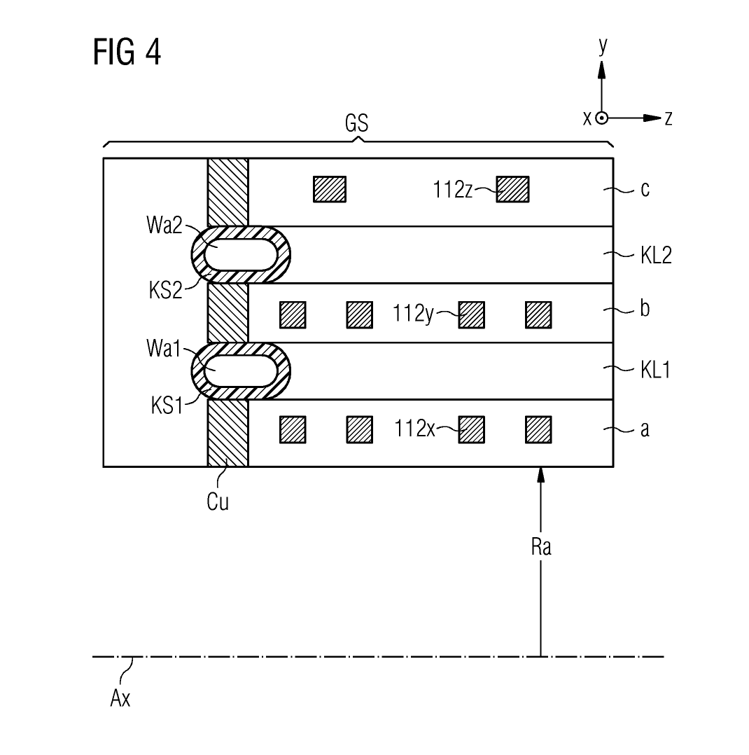

FIG. 4 shows a schematic and simplified view of one embodiment of a gradient coil system GS (e.g., of a magnetic resonance tomography device 101) having three coil layers a, b, c. The three coil layers a, b, c are provided with gradient coils 112x, 12y, 112z therein for the generation, in each case, of a temporally changeable gradient magnetic field B_{G}(x, y, z, t) in one of three directions (e.g., arranged orthogonal to one another; in the x-direction, y-direction, z-direction).

The coil layers a, b, c and cooling layers KL1, KL2 may be arranged, for example, so as to surround a cylindrical axis Ax of the MRT bore 103 (e.g., MRT opening; including a radius Ra).

A first cooling layer KL1, which includes, for example, one or a number of cooling hoses KS1 as a cooling element (e), is arranged between a first (a) and a second (b) of the coil layers a, b, c. A cooling medium (e.g., water Wa1) passes through the cooling hoses KS1.

A second cooling layer KL2, which includes, for example, one or a number of cooling hoses KS2 as a cooling element(s), is arranged between a second (b) and a third (c) of the coil layers a, b, c. A cooling medium (e.g., water Wa2) passes through the cooling hoses KS2.

For the sake of clarity, only one winding of a cooling hose KS1 (similarly KS2) is shown in FIG. 4 in each instance in a cross-section. A number of windings (e.g., in the z-direction) may be adjacent to one another, or several cooling hoses KS1 (e.g., in the z-direction) may adjacent to one another in a cooling layer KL1, KL2.

Cooling hoses KS may be integrated in a manner known, for example, and/or may be connected to a circulating pump and/or a cooling unit.

At least one cooling layer KL1, KL2 is arranged in the immediate vicinity of each of the three coil layers a, b, c (e.g., rests directly thereupon or is separated by a thin electrically insulating layer and/or supporting arrangement).

Radial conductor cross-sections of conductors 112x, 112y, 112z in the coil layers a, b, c may be smaller than the radial conductor cross-sections would be without two cooling layers on account of the two cooling layers KL1, KL2.

One advantage may be that a structure of a gradient coil arrangement is layered, which, compared with the prior art, may be energized more significantly with a similar permissible operating temperature (e.g., may be applied with current) and may thus enable higher nominal gradient fields. A cooling layer KL1, KL2 may be arranged in the immediate vicinity of each coil layer a, b, c. The thermal transition resistance between a cooling layer KL1 of the cooling layers and the coils (e.g., 12×) remote from the cooling according to FIG. 2 may be reduced as a result.

In order not to increase the overall installation space and/or be able to disadvantageously shift conductor radii outwards, the conductor cross-sections (radial) may be reduced in this embodiment in order to obtain space (e.g., compared with the known prior art with only one cooling layer) for the additional cooling layers. If the cooling layers are embodied to be very thin, the reduction in the conductor height with the accompanying increased loss of power may be secondary compared with the gain in the heat reducing performance (or the cooling output).

Possible advantages may be a more effective cooling of the coil windings and/or reduced thermal resistance of the coil axis remote from the cooler relative to the cooling medium. As a result, operation of the gradient coil with higher current strengths (e.g., higher nominal gradient strengths with the same permissible maximum temperature) may be provided. Temperature peaks may be avoided in the region of tightly wound conductors in the coil planes. As a result, more even temperature distribution and less thermomechanical voltages in the coil structure may be provided. Optimization may be provided in terms of assembly of high-performance coils in a small installation space.

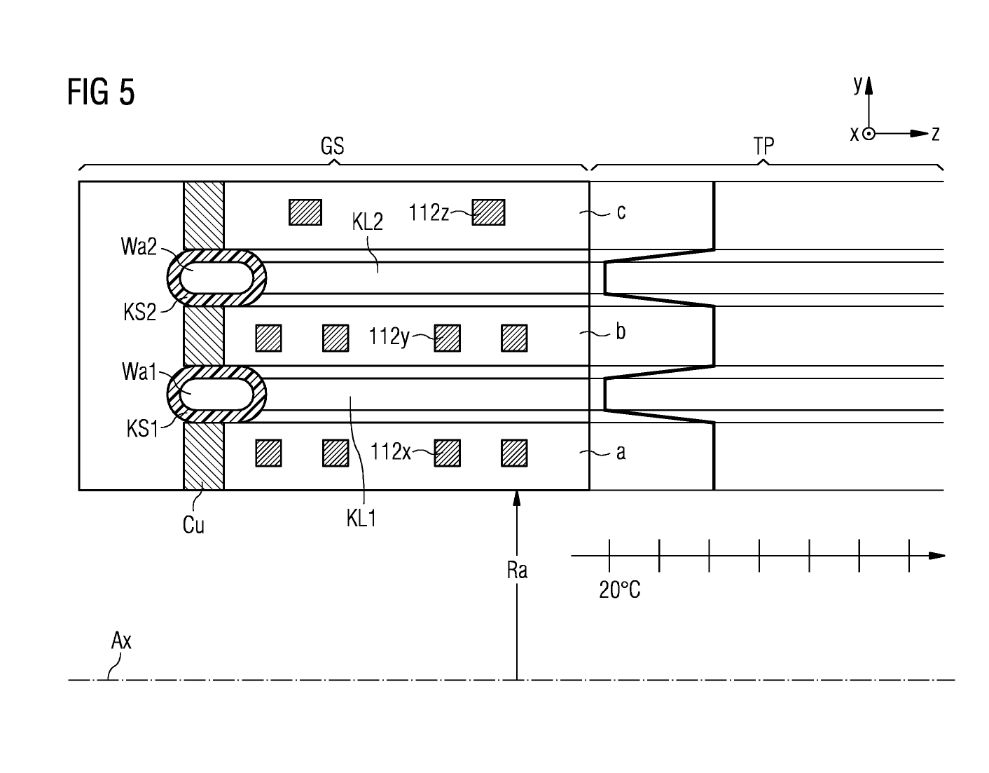

FIG. 5 shows a view as in FIG. 4, extended by a simplified, schematic temperature profile TP. On account of the coolant, the temperature in the cooling layers is at its lowest and is higher than in the coolant in the coils 112x, 112y, 112z of the coil layers a, b, c, and is just as high as in the two outer coil layers a, b in the innermost coil layer c.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A magnetic resonance tomography device comprising:
three coil layers, each coil layer of the three coil layers operable to generate a gradient magnetic field in a direction;
a first cooling layer arranged between a first coil layer of the three coil layers and a second coil layer of the three coil layers; and
a second cooling layer arranged between the second coil layer and a third coil layer of the three coil layers.

2. The magnetic resonance tomography device as claimed in claim 1, wherein the first cooling layer and the second cooling layer are cooling layers with cooling elements.

3. The magnetic resonance tomography device as claimed in claim 2, wherein the cooling elements comprise cooling hoses.

4. The magnetic resonance tomography device as claimed in claim 1, wherein the first cooling layer, the second cooling layer, or the first cooling layer and the second cooling layer comprise cooling elements including cooling hoses filled with a coolant.

5. The magnetic resonance tomography device as claimed in claim 1, wherein the first cooling layer, the second cooling layer, or the first cooling layer and the second cooling layer comprise cooling elements including cooling hoses, the cooling hoses each being connected to a pump and a cooling unit.

6. The magnetic resonance tomography device as claimed in claim 1, further comprising gradient coils arranged in the three coil layers.

7. The magnetic resonance tomography device as claimed in claim 1, further comprising gradient coils arranged in the three coil layers, each of the gradient coils operable to generate a gradient magnetic field in one of three directions.

8. The magnetic resonance tomography device as claimed in claim 7, wherein the directions of the gradient coils in the three coil layers of generateable gradient magnetic fields are three directions orthogonal to one another.

9. The magnetic resonance tomography device as claimed in claim 8, wherein the three directions orthogonal to one another are the x-direction, the y-direction, and the z-direction.

10. The magnetic resonance tomography device as claimed in claim 1, wherein at least one cooling layer of the first cooling layer and the second cooling layer is arranged adjacent to each of the three coil layers.

11. The magnetic resonance tomography device as claimed in claim 3, wherein the first cooling layer, the second cooling layer, or the first cooling layer and the second cooling layer comprise cooling elements including cooling hoses filled with a coolant.

12. The magnetic resonance tomography device as claimed in claim 3, wherein the first cooling layer, the second cooling layer, or the first cooling layer and the second cooling layer comprise cooling elements including cooling hoses, the cooling hoses each being connected to a pump and a cooling unit.

13. The magnetic resonance tomography device as claimed in claim 3, further comprising gradient coils arranged in the three coil layers.

14. The magnetic resonance tomography device as claimed in claim 4, further comprising gradient coils arranged in the three coil layers.

15. The magnetic resonance tomography device as claimed in claim 5, further comprising gradient coils arranged in the three coil layers.

16. The magnetic resonance tomography device as claimed in claim 3, further comprising gradient coils arranged in the three coil layers, each of the gradient coils operable to generate a gradient magnetic field in one of three directions.

17. The magnetic resonance tomography device as claimed in claim 4, further comprising gradient coils arranged in the three coil layers, each of the gradient coils operable to generate a gradient magnetic field in one of three directions.

18. The magnetic resonance tomography device as claimed in claim 5, further comprising gradient coils arranged in the three coil layers, each of the gradient coils operable to generate a gradient magnetic field in one of three directions.

19. The magnetic resonance tomography device as claimed in claim 3, wherein at least one cooling layer of the first cooling layer and the second cooling layer is arranged adjacent to each of the three coil layers.

20. The magnetic resonance tomography device as claimed in claim 8, wherein at least one cooling layer of the first cooling layer and the second cooling layer is arranged adjacent to each of the three coil layers.
